(19) United States
(12) Patent Application Publication
(10) Pub. No.: US 2013/0014808 A1
(43) Pub. Date: Jan. 17, 2013

(54) PHOTOVOLTAIC MODULES AND METHODS FOR MAKING AND USING THE SAME

(71) Applicants: Marcel Brounne, Etten-Leur (NL); Cornelis Johannes Gerardus Maria van Peer, Halsteren (NL); Przemyslaw Olszynski, Bergen op Zoom (NL)

(72) Inventors: Marcel Brounne, Etten-Leur (NL); Cornelis Johannes Gerardus Maria van Peer, Halsteren (NL); Przemyslaw Olszynski, Bergen op Zoom (NL)

(73) Assignee: SABIC INNOVATIVE PLASTICS IP B.V., Bergen op Zoom (NL)

(21) Appl. No.: 13/542,878

(22) Filed: Jul. 6, 2012

Related U.S. Application Data
(60) Provisional application No. 61/507,775, filed on Jul. 14, 2011.
(60) Provisional application No. 61/664,847, filed on Jun. 27, 2012.

(51) Int. Cl. H01L 31/048; H01L 31/18

(52) U.S. Cl. 136/251; 438/66; 257/E31.117

(57) ABSTRACT

A photovoltaic module assembly can comprise a photovoltaic cell; a transparent first layer comprising a plastic material, wherein the first layer has a first layer first surface and a first layer second surface; a second layer, wherein the second layer has a second layer first surface and a second layer second surface, wherein the photovoltaic cell is between the first layer second surface and the second layer first surface; and a cured layer between the first layer second surface and the second layer first surface, wherein the cured layer is a liquid having a viscosity of less than or equal to 1,500 centipoise before curing.

Disclosed herein are photovoltaic (PV) module assemblies, and specifically, thermoplastic crystalline silicon solar PV module assemblies.

### BACKGROUND

A PV module usually comprises a collector, such as a flat sheet generally made from a transparent or semi-transparent material such as glass, a polymer, or like materials. Mechanical performance requirements must be met for the PV module to function effectively and as desired. For example, for forming the collector, the polymer poly(methyl methacrylate) is good for light transmission (i.e., high optical efficiency), but lacks impact resistance and flame retardance, and is thus, difficult to use. Polycarbonate has good mechanical properties for producing the flat sheet, but has a lower optical efficiency.

In addition, the PV cell must be connected to the collector. The PV cell, which is generally mostly silicon, is usually more fragile than the collector, which is mostly polymeric. Failure means, such as corrosion and delamination potentially exist, so there is a need for PV module assemblies with, increased production rates, reduced assembly times, and decreased weight.

### SUMMARY

Disclosed, in various embodiments, are photovoltaic modules, and methods for making and using the same.

In an embodiment, a photovoltaic module assembly, comprises: a photovoltaic cell; a transparent first layer comprising a plastic material, wherein the first layer has a first layer first surface and a first layer second surface; a second layer, wherein the second layer has a second layer first surface and a second layer second surface, wherein the photovoltaic cell is between the first layer second surface and the second layer first surface; and a cured layer between the first layer second surface and the second layer first surface, wherein the cured layer is a fluid having a viscosity of less than or equal to 1,500 centipoise before curing.

In an embodiment, a photovoltaic module assembly, comprises: a photovoltaic cell; a transparent first layer comprising a plastic material, wherein the first layer has a first layer first surface and a first layer second surface; a second layer comprising a plastic material, wherein the second layer has a second layer first surface and a second layer second surface, wherein the photovoltaic cell is between the first layer second surface and the second layer first surface; a connecting layer disposed between the first layer second surface and the second layer first surface, wherein the connecting layer forms a gap between the first layer first surface and the second layer second surface, wherein the photovoltaic cell is in the connecting layer; and a cured layer in the gap, between the first layer and the photovoltaic cell.

In an embodiment, a method of making a photovoltaic module assembly, comprises: disposing a photovoltaic cell between a first layer having a first layer first surface and a first layer second surface and a second layer having a second layer first surface and a second layer second surface, wherein the first layer is transparent and comprises a plastic material and wherein the second layer comprises a plastic material; inserting a liquid filling between the first layer and the second layer, wherein the liquid filling has a viscosity of less than or equal to 1,500 centipoise before curing; and curing the liquid filling.

In an embodiment, a photovoltaic module assembly comprises a photovoltaic cell; a transparent first layer comprising a plastic material; a second layer comprising a plastic material, wherein the second layer is in physical communication with the photovoltaic cell; and a fluid layer between the first layer and the photovoltaic cell; wherein the fluid layer has a viscosity between 0 to 1,000 centipoise.

In an embodiment, a method of making a photovoltaic module assembly comprises disposing a photovoltaic cell between a first layer and a second layer, wherein the first layer is transparent and comprises a plastic material and wherein the second layer comprises a plastic material; and disposing a fluid layer between the first layer and the photovoltaic cell, wherein the fluid layer has a viscosity of 0 to 1,000 centipoise.

These and other features and characteristics are more particularly described below.

### BRIEF DESCRIPTION OF THE DRAWINGS

The following is a brief description of the drawings wherein like elements are numbered alike and which are presented for the purposes of illustrating the exemplary embodiments disclosed herein and not for the purposes of limiting the same.

FIG. 1 is a schematic representation of the individual components of a PV module assembly.

FIG. 2 is an assembled view of the PV module of FIG. 1.

FIG. 3 is an expanded cross sectional side view of the PV module assembly of FIG. 1.

FIG. 4 is another expanded cross sectional side view of the PV module assembly of FIG. 1.

FIG. 5 is a front view of a PV module assembly comprising a connecting layer.

### DETAILED DESCRIPTION

PV cells, which are optically coupled to a collector, are generally mostly silicon, while the collector can generally be mostly polymeric. These materials have very different coefficients of thermal expansion (CTE). In other words, when exposed to heat, they expand at different rates. This mismatch needs to be addressed to ensure that the PV cell does not break as the two components change dimensions. PV module assemblies can generally comprise a frame, junction box, cables, connectors, a ground fault circuit interrupter (GFCI), a mounting system, a tracking system, a combiner box, a back layer, encapsulant layers (e.g., ethylene vinyl acetate encapsulant layers), wafers (i.e., PV cells), an anti-reflective layer, and/or a front layer of glass. The frame, when present, can generally be made of aluminum. The aluminum frame and the glass layer are the biggest contributors to the weight of the PV module assemblies, which can make the assemblies generally heavy and expensive to produce. Glass accounts for the largest part of the weight of a PV module assembly.

As disclosed herein, a PV module assembly can comprise a first layer, a fluid layer and/or a cured layer, a photovoltaic cell, a second layer having an optional integrated frame, a junction box, cables, and a micro-inverter, and an optional connecting layer connecting the first layer to the second layer.

Replacing the glass in a PV module assembly allows for a much lighter assembly (e.g., 10 kilograms per square meter (kg/m²) for assemblies without glass as compared to 13 kg/m² for assemblies with glass), which can allow placement on roofs having limited load bearing capacity (e.g., flat roofs). For example, the weight of a PV module assembly can be reduced by replacing the glass layer with a plastic layer (e.g., the first layer) and/or optionally, replacing the aluminum frame and back layer (e.g., second layer) with an integrated plastic frame in the second layer (e.g., polycarbonate or blends of polyphenylene ether and polystyrene). In some embodiments, a connecting layer can be utilized to connect a first layer and a second layer, eliminating the frame altogether and further decreasing the weight of the assembly. For example, the connecting layer can comprise an adhesive (e.g., tape) that can be used to act as a spacer between layers of the PV module assembly and to act as a structural adhesive connecting the layers together. PV module assemblies with fewer components or with components that are integrated with one another (e.g., the junction box, cables, and/or connectors integrated with the frame) can decrease the amount of time necessary for production and assembly of the PV module.

A fluid layer (e.g., silicone fluid (silicone liquid, silicone oil) and/or a cured layer (e.g., room temperature vulcanize silicone, and/or rubber or thermoset elastomer silicone and/or other silicone adhesives) can optionally be used as an encapsulant to help provide an optical coupling between the first layer and the PV cells, meaning that light passes through the first layer and reaches the photovoltaic cells with minimal reflective losses (e.g., the fluid layer and the PV cells are in optical communication with one another) and/or between the PV cells and the second layer. The fluid layer and/or cured layer can also act as a cushion and can decouple mechanical movement between the first layer and the PV cells. For example, in mechanical decoupling, the fluid layer and/or cured layer will not transfer force from the first layer to the PV cells due to its liquid nature. The use of the fluid layer and/or cured layer can also be advantageous because the refractive index of the fluid layer and/or cured layer can be chosen so that the optical performance of the system is enhanced (e.g., maximum light transmission through the first layer to the PV cells can be achieved). The refractive index can also be chosen to ensure minimal reflective losses between the first layer, the encapsulant (i.e., the fluid layer and/or the cured layer), and the solar cells.

Additionally, by using a non-laminating assembly, the cells can be recovered during the manufacturing process if any faults are detected and the cells can easily be reused after the useful life of the module. This reduces the carbon footprint of such a system. The fluid layer and/or cured layer, when present, can also protect the PV cells against moisture and transfer heat away from the cells, leading to a higher efficiency at high operating temperatures.

Turbulent airflow, which functions to cool the PV module, can be created by aerodynamic features integrated in the second layer. The first layer can also, optionally, be textured to decrease light reflection. Both the turbulent air flow and the texturing can provide higher energy yield during a PV module's lifetime under different circumstances, such as sunlight entering at an angle, high ambient temperatures, and partial shading of the PV module. For example, the aerodynamic features can include, but are not limited to fins, ribs, baffles, and combinations comprising at least one of the foregoing. Turbulent air flow and texturing, when integrated into a PV module can reduce cost, decrease production times, and reduce the weight of the PV module as well as optimize the yield of a system during its useful lifetime.

A more complete understanding of the components, processes, and apparatuses disclosed herein can be obtained by reference to the accompanying drawings. These figures (also referred to herein as “FIG.”) are merely schematic representations based on convenience and the ease of demonstrating the present disclosure, and are, therefore, not intended to indicate relative size and dimensions of the devices or components thereof and/or to define or limit the scope of the exemplary embodiments. Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

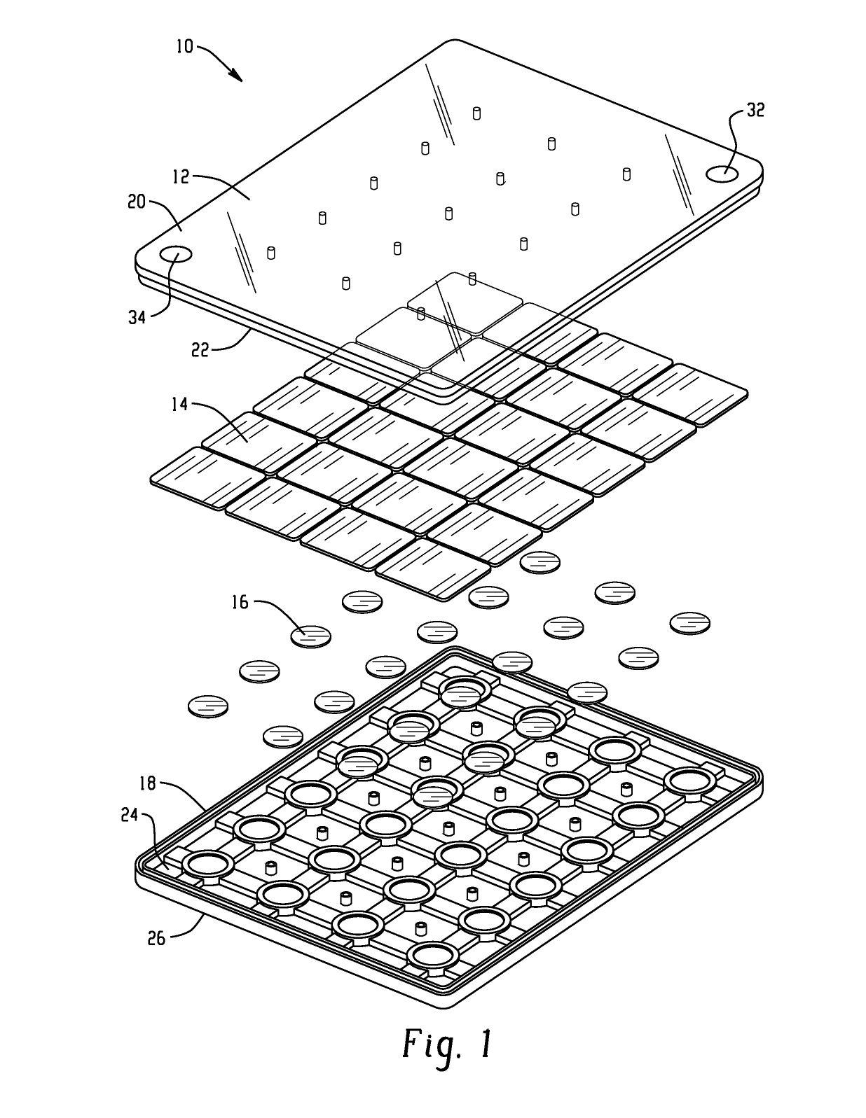

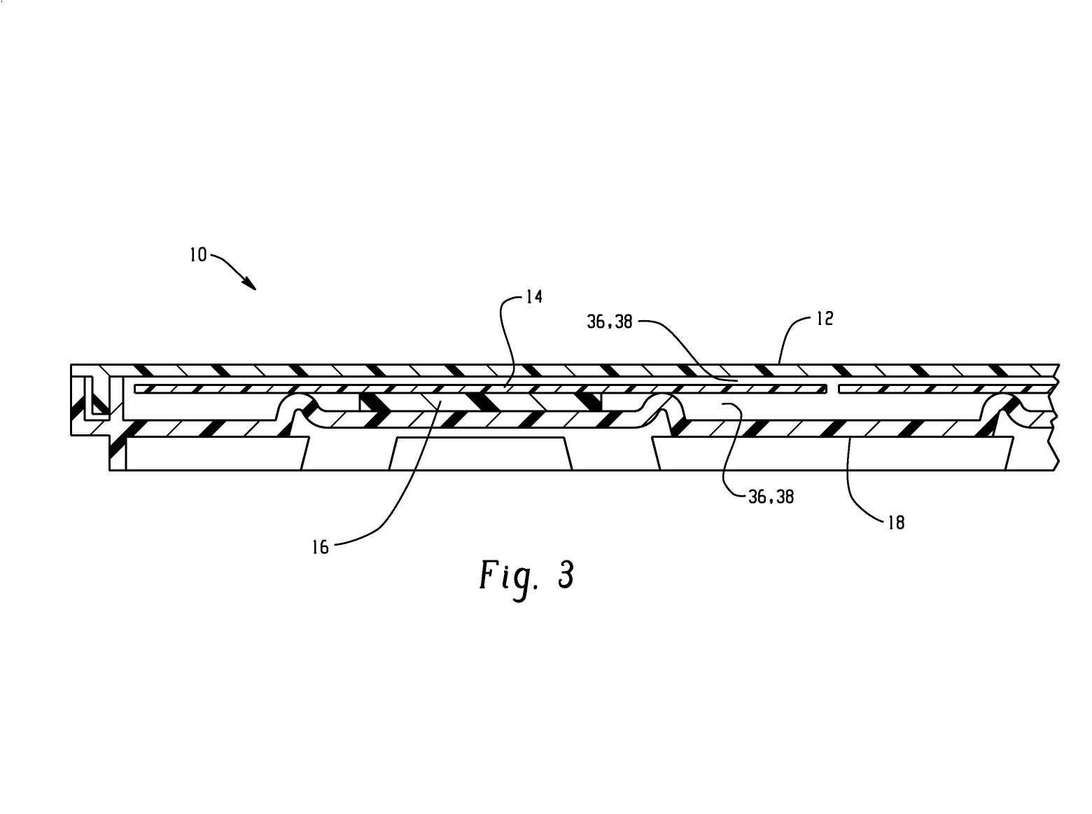

FIG. 1 illustrates a schematic view of the individual components of a PV module 10. FIG. 1 illustrates that a first layer 12 can be optically coupled to the PV cells 14 by a fluid layer (e.g., an encapsulant (see FIG. 3, such as silicone fluid)) and/or a cured layer between the first layer 12 and the PV cells 14. The first layer 12 and/or the second layer 18 can additionally comprise a silicone hardcoat and/or a plasma deposition layer on the outermost surface of the first layer 12 and/or the second layer 18 to ensure a 20 year lifetime span for the PV module assembly. An adhesive (e.g., silicone gel pads 16 or room temperature vulcanize silicone 16 in FIG. 3) can secure the PV cells 14 to the second layer 18. The first layer 12 can have a first layer first surface 20 and a first layer second surface 22, while the second layer 18 can have a second layer first surface 24 and a second layer second surface 26.

It can be desirable for the first layer and the second layer to have certain optical properties. For example, the first layer can be transparent, while the second layer can be transparent, semi-transparent, or opaque. With regards to the transparency of the first layer and/or the second layer, it is briefly noted that end user specifications can generally specify that the first layer and/or the second layer satisfy a particular predetermined threshold. Haze values, as measured by ANSI/ASTM D1003-00, can be a useful determination of the optical properties of the first layer and/or second layer. The lower the haze levels, the higher the transparency of the individual layer. It can be desirable to monitor the haze levels of the first layer and/or the second layer. Exemplary haze levels for the transparent first layer, when measured at a thickness of 5.0 millimeters (mm), can be 0% to 6%, specifically 0.5% to 4%, and more specifically 1% to 2.5%. Exemplary haze levels for the second layer, when measured at a thickness of 5.0 mm, can be generally greater than 6%, specifically, greater than or equal to 10%. The first layer can have a transparency of greater than or equal to 80%, specifically, greater than or equal to 85%, more specifically, greater than or equal to 90%, even more specifically, greater than or equal to 95%, and still more specifically, greater than or equal to 99%, as measured in accordance with ASTM D1003-00, Procedure A or Procedure B, using lamp D65. The second layer can generally be opaque, but can also be transparent if desired, for example, for aesthetic reasons. For example, the second layer can have a transparency of greater than or equal to 50%, specifically, greater than or equal to 65%, more specifically, greater than or equal to 75%, and even more specifically, less than or equal to 90%. Transparency is described by two parameters, percent transmission and percent haze. Percent transmission and percent haze for laboratory scale samples can be determined using ASTM D1003-00, Procedure B using CIE standard illuminant C. ASTM D-1003-00 (Procedure B, Spectrophotometer, using illuminant C with diffuse illumination with unidirectional viewing) defines transmittance as:

$$\% T = ( \frac{I}{{I}_{O}} ) \times 100 \% \qquad ( 1 )$$

wherein: I=intensity of the light passing through the test sample
Iₒ=Intensity of incident light.

Haze can be measured in accordance with ASTM D-1003-00, Procedure A, measured, e.g., using a HAZE-GUARD DUAL from BYK-Gardner, using and integrating sphere (0°/diffuse geometry), wherein the spectral sensitivity conforms to the CIE standard spectral value under standard lamp D65. ASTM D1003-00, Procedure B can also use a Macbeth 7000A spetrometer, D65 illuminant, 10° observer, CIE (Commission Internationale de L'Eclairage) (1931), and SCl (specular component included), and UVEXC (i.e., the UV component is excluded); while haze uses the same variables with Procedure A. It is noted that the percent haze can be predicted and calculated from the following equation:

$$\% Haze = 100 \times \frac{Total Diffuse Transmission}{Total Transmission} \qquad ( 2 )$$

wherein total transmission is the integrated transmission; and the total diffuse transmission is the light transmission that is scattered by the film as defined by ASTM D1003-00. For example, a commercially available hazemeter can be used, such as the BYK-Gardner Haze-Gard Plus, with the rough diffusing side of the film facing the detector.

It can be desirable for the refractive index of the first layer and the second layer to be close to (e.g., within about 20%) the refractive index of the fluid layer; it can also be desirable for the coefficient of thermal expansion of the first layer and the second layer to be close (e.g., within about 15% of each other). Further, it can be desirable for the PV module assembly to pass the impact test requirements as set forth in UL 1703. Flame retardance as tested according to the standard of the Underwriters Laboratory 94 (UL 94) of the layers can be another factor to consider when selecting materials for the first layer and the second layer. For example, the UL 94 rating should desirably be V0 or greater (e.g., 5 VB or 5 VA). The first layer and the second layer can also desirably have an ultraviolet light stability of 20 years such that they retain greater than or equal to 80% of their light transmission capabilities over that 20 year period.

With respect to the fluid layer, the viscosity of this layer can be less than or equal to 1,000 centipoise (cps), specifically, 0 to 1,000 centipoise, more specifically, 0 to 500 centipoise, even more specifically, 0 to 250 centipoise, still more specifically, 0 to 100 centipoise, yet more specifically, 5 to 90 centipoise, and yet more specifically still, 10 to 75 centipoise. With respect to the cured layer (e.g., comprising silicone room temperature vulcanize (RTV), silicone thermoset elastomer (TSE), etc.), the viscosity of this layer can be less than or equal to 1,500 centipoise, specifically, less than or equal to 1,000 centipoise, more specifically, less than or equal to 950 centipoise, and even more specifically, less than or equal to 750 centipoise before curing, but generally greater than or equal to 500 centipoise, before curing. Viscosities of less than or equal to 1,500 centipoise facilitate insertion (e.g., pouring) of the liquid filling into a gap created by the connecting layer between the first layer and the second layer. Materials having a before curing viscosity of greater than 1,500 centipoise would be difficult to and most likely cannot be inserted into the gap.

The refractive index of the fluid layer and/or cured layer can be close in value to the refractive index of the first layer material (e.g., within 15% of the refractive index of the first layer). For example, if the refractive index of the first layer is 1.0, then the refractive index of the fluid layer and/or cured layer would be 0.85 to 1.15. The transparency of the fluid layer and/or cured layer can be greater than or equal to 95%, specifically, greater than or equal to 99%, and even more specifically, greater than or equal to 99.9%. as measured according to ASTM D1003-00. It can be advantageous for the thermal conductivity of the fluid layer and/or cured layer to be as high as possible.

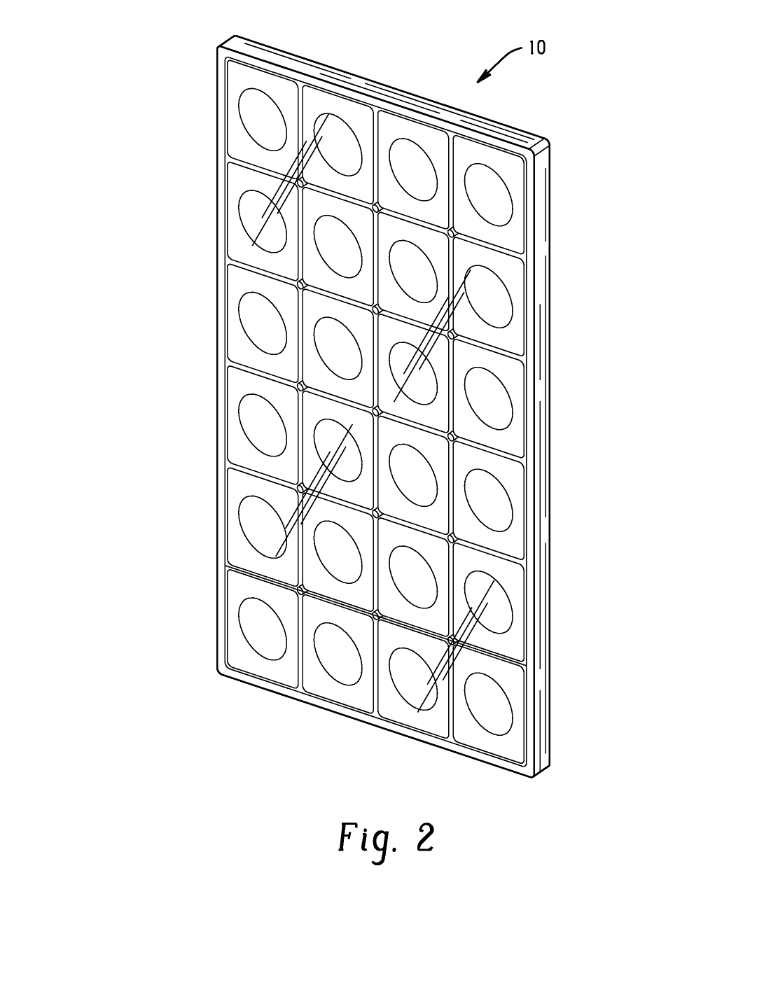

The second layer 18 can generally comprise a frame, a junction box, cables, connectors, mounting points for mounting to an external structure, and an inverter (e.g., a micro-inverter). Integration of all of these components into the second layer 18 can offer significant savings in production time, assembly time, and cost compared to a PV module where each component is produced separately and has to be assembled after production. FIG. 2 illustrates an assembled view of the components illustrated in FIG. 1.

In embodiments such as those illustrated in FIG. 5, the frame can be an optional component of the assembly. For example, when a connecting layer 28 is present, and as illustrated in FIG. 5, the connecting layer 28 (e.g., structural layer) can be located around a perimeter (i.e., on the edges of) of the first layer 12 and the second layer 18. For example, the connecting layer 28 can be disposed between and in physical contact with the outer periphery of the first layer second surface 22 and the outer periphery of the second layer first surface 26 forming a gap 30 between the first layer 12 and the second layer 18. The connecting layer 28 can comprise any material that will provide the desired adhesion between the first layer 12 and the second layer 18, for example, the connecting layer can comprise an acrylic (e.g., acrylic tape or acrylic foam tape) or an acetate (e.g., ethylene vinyl acetate (EVA) foam tape. In other words, the connecting layer can be any adhesive having sufficient structural integrity and compatibility with the first layer and the second layer to inhibit delamination. For example, the adhesive tape can have an adhesive strength of greater than or equal to about 0.1 megaPascals (MPa), or, more specifically, greater than or equal to about 0.2 MPa, as determined in accordance with ISO 4587-1979 (Adhesives-Determination of tensile lap shear strength of high strength adhesive bonds). The elongation at break of the adhesive tape can be greater than or equal to about 50%, or, more specifically, greater than or equal to about 80%, or, even more specifically, greater than or equal to about 95%, as measured in accordance with ISO 4587-1979 (Adhesives-Determination of tensile lap shear strength of high strength adhesive bonds).

The adhesive tape can be located between, and near the periphery (e.g., edge), of the first layer and the second layer. The adhesive tape can act as a structural adhesive to form a gap between the first layer and the second layer, into which the liquid filling can be inserted (e.g., poured). The adhesive tape, can have a thickness of about 0.5 mm to about 10 mm, or, more specifically, about 1.0 mm to about 5.0 mm. The adhesive tape can have a width that is less than or equal to about 50% of a total surface area of the layer (e.g., the layer to which is it applied), or, more specifically, about 1% to about 40% of the total surface area, and, yet more specifically, about 2% to about 20% of the total surface area. The adhesive can be located in the outer 40% of the first layer and/or the second layer (measuring from a center of the respective layer toward the edge of the respective layer), or, more specifically, in the outer 25%, and yet more specifically, in the outer 10%. For example, if the layer has a width of 1.0 meter (m), the adhesive tape would be located between the outer edge and 0.4 m from the outer edge, or, more specifically, between the outer edge and 0.25 m from the outer edge, and yet more specifically, between the outer edge and 0.1 m from the outer edge.

A fluid layer and/or cured layer as herein described can be located in the gap 30 (e.g., a liquid material can be inserted into the gap 30 through a filling opening 32 which can optionally be located on the first layer first surface 20). A degassing opening 34 can also be present on the first layer first surface 20. After inserting the liquid material into the filling opening 32, the filling opening 32 and the degassing opening 34 can be closed (e.g., with a plug, button (e.g., plastic button), etc.). The degassing opening 34 can be capable of venting gas generated when the liquid material is inserted into the filling opening.

The fluid layer can comprise silicone fluid (i.e., silicone oil) and the cured layer can comprise a liquid room temperature vulcanize filling (liquid filling); and/or a rubber or thermoset elastomer (TSE). For example, the fluid layer can comprise silicone room temperature vulcanize filling (silicone RTV) and/or silicone fluid; and/or silicone rubber or thermoset elastomer (silicone TSE); and/or a silicone adhesive such as silicone tape. The silicone RTV and silicone TSE can be subject to a thermal cure. For example, the silicone RTV can, optionally, contain a catalyst that can allow for faster room temperature curing, whereas the silicone TSE can cure under elevated temperatures (e.g., greater than or equal to 60° C.) to decrease the curing time or, can cure at room temperature when the silicone TSE contains a catalyst. For example, the liquid filling can have a viscosity that does not form bubbles visible to the unaided eye during pouring into the gap and can have a storage modulus (G′) that varies by less than or equal to 200 Pascals (Pa) over a temperature range of −40° C. to 200° C. For example, the fluid layer can be formed from a liquid having a viscosity that does not form bubbles during pouring into the gap 30, and that has a loss modulus that deviates by a factor of less than or equal to about 1,000 (or, more specifically, by a factor of less than or equal to about 500) over a temperature range of 40° C. to 200° C. The liquid filling can be prepared at a viscosity that will enable the filling of the gap 30, with little or no inclusions. Once in the gap 30, the liquid filling cures, completing formation of the PV module assembly 10.

The cured layer can generally have a viscosity of less than or equal to 1,500 centipoise, specifically, less than or equal to 1,000 centipoise, more specifically, less than or equal to 950 centipoise, and even more specifically, less than or equal to 750 centipoise before curing, but generally greater than or equal to 500 centipoise before curing. For example, before curing, the cured layer can have a viscosity of less than or equal to 1,500 centipoise, but greater than or equal to 500 centipoise.

As mentioned, the first layer 12 and/or the second layer 18 can comprise a thermoplastic material. Possible thermoplastic resins that can be employed for the first layer 12 and/or second layer 18 include, but are not limited to, oligomers, polymers, ionomers, dendrimers, copolymers such as block copolymers, graft copolymers, star block copolymers, random copolymers, and combinations comprising at least one of the foregoing having the desired optical properties for a PV application. Examples of such thermoplastic resins include, but are not limited to, polycarbonates (e.g., polycarbonate-polybutadiene blends, blends of polycarbonate, copolyester polycarbonates), polystyrenes (e.g., copolymers of polycarbonate and styrene), acrylonitrile-styrene-butadiene, polyphenylene ether-polystyrene resins, polyalkylmethacrylates (e.g., poly(methyl methacrylates)), polyesters (e.g., copolyesters, polythioesters), polyolefins (e.g., polypropylenes and polyethylenes, high density polyethylenes, low density polyethylenes, linear low density polyethylenes), polyamides (e.g., polyamideimides), polyethers (e.g., polyether ketones, polyether etherketones, polyethersulfones), and combinations comprising at least one of the foregoing.

More particularly, the thermoplastic material used in the first layer 12 and/or the second layer 18 can include, but are not limited to, polycarbonate resins (e.g., LEXAN* resins, commercially available from SABIC Innovative Plastics), polyphenylene ether-polystyrene resins (e.g., NORYL* resins, commercially available from SABIC Innovative Plastics), polyetherimide resins (e.g., ULTEM* resins, commercially available from SABIC Innovative Plastics), polybutylene terephthalate-polycarbonate resins (e.g., XENOY* resins, commercially available from SABIC Innovative Plastics), copolyestercarbonate resins (e.g. LEXAN* SLX resins, commercially available from SABIC Innovative Plastics), and combinations comprising at least one of the foregoing resins. Even more particularly, the thermoplastic resins can include, but are not limited to, homopolymers and copolymers of: a polycarbonate, a polyester, a polyacrylate, a polyamide, a polyetherimide, a polyphenylene ether, or a combination comprising at least one of the foregoing resins. The polycarbonate can comprise copolymers of polycarbonate (e.g., polycarbonate-polysiloxane, such as polycarbonate-polysiloxane block copolymer), linear polycarbonate, branched polycarbonate, end-capped polycarbonate (e.g., nitrile end-capped polycarbonate), and combinations comprising at least one of the foregoing, for example a combination of branched and linear polycarbonate.

The first layer 12 and/or the second layer 18 can include various additives ordinarily incorporated into polymer compositions of this type, with the proviso that the additive(s) are selected so as to not significantly adversely affect the desired properties of the PV module assembly 10, in particular, energy yield and weight savings.

Examples of additives that can be included in the various layers of the PV module include optical effects filler, impact modifiers, fillers, reinforcing agents, antioxidants, heat stabilizers, light stabilizers, ultraviolet (UV) light stabilizers, plasticizers, lubricants, mold release agents, antistatic agents, colorants (such as carbon black and organic dyes), surface effect additives, radiation stabilizers (e.g., infrared absorbing), gamma stabilizer, flame retardants, and anti-drip agents. A combination of additives can be used, for example a combination of a heat stabilizer, mold release agent, and ultraviolet light stabilizer. In general, the additives are used in the amounts generally known to be effective. Each of these additives can be present in amounts of 0.0001 to 10 weight percent (wt. %) 0.001 to 5 wt. %, based on the total weight of the PV module assembly 10 and/or layer in which the additive is incorporated.

The first layer 12 and/or the second layer 18 can optionally comprise a flame retardant. Flame retardants include organic and/or inorganic materials. Organic compounds include, for example, phosphorus, sulphonates, and/or halogenated materials (e.g., comprising bromine chlorine, and so forth, such as brominated polycarbonate). Non-brominated and non-chlorinated phosphorus-containing flame retardant additives can be preferred in certain applications for regulatory reasons, for example organic phosphates and organic compounds containing phosphorus-nitrogen bonds.

Inorganic flame retardants include, for example, C₁₋₁₆ alkyl sulfonate salts such as potassium perfluorobutane sulfonate (Rimar salt), potassium perfluorooctane sulfonate, tetraethyl ammonium perfluorohexane sulfonate, and potassium diphenylsulfone sulfonate (e.g., KSS); salts such as Na₂CO₃, K₂CO₃, MgCO₃, CaCO₃, and BaCO₃, or fluoro-anion complexes such as Li₃AlF₆, BaSiF₆, KBF₄, K₃AlF₆, KAlF₄, K₂SiF₆, and/or Na₃AlF₆. When present, inorganic flame retardant salts are present in amounts of 0.01 to 10 parts by weight, more specifically 0.02 to 1 parts by weight, based on 100 parts by weight of the total composition of the layer of the PV module assembly 10 in which it is included (i.e., the first layer 12 or the second layer 18), excluding any filler.

Anti-drip agents can also be used in the composition forming the first layer 12 and/or the second layer 18, for example a fibril forming fluoropolymer such as polytetrafluoroethylene (PTFE). The anti-drip agent can be encapsulated by a rigid copolymer, for example styrene—acrylonitrile copolymer (SAN). PTFE encapsulated in SAN is known as TSAN. An exemplary TSAN comprises 50 wt. % PTFE and 50 wt. % SAN, based on the total weight of the encapsulated fluoropolymer. The SAN can comprise, for example, 75 wt. % styrene and 25 wt. % acrylonitrile based on the total weight of the copolymer. Anti-drip agents can be used in amounts of 0.1 to 10 parts by weight, based on 100 parts by weight of the total composition of the particular layer, excluding any filler.

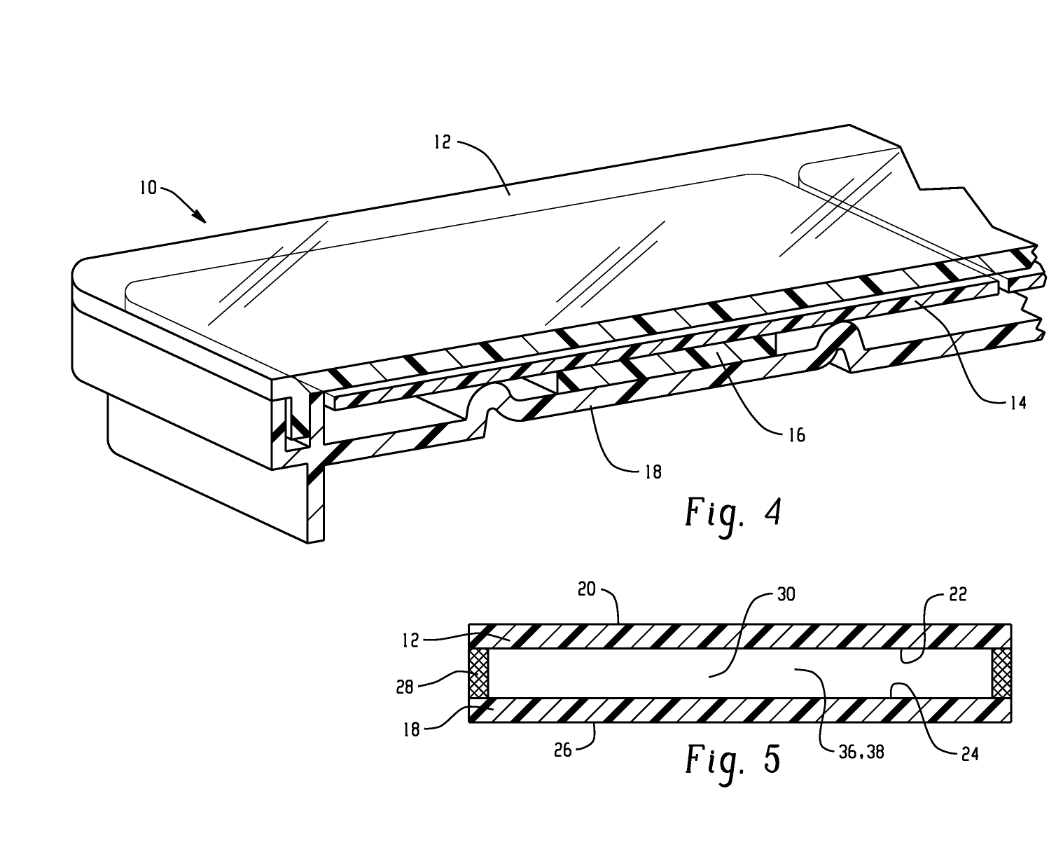

In FIG. 3, a PV module assembly 10 is illustrated. As illustrated in FIG. 3, a fluid layer 36 (e.g., silicone oil) and/or a cured layer 38 (e.g., silicone RTV and/or silicone TSE) can be dispersed between the first layer 12 and the PV cells 14 thereby encapsulating the PV cells 14. The PV cells 14 can optionally be connected to the second layer 18 through an additional adhesive 16 (e.g., room temperature vulcanize (RTV) and/or silicone gel, wherein the RTV, when used as an adhesive is in addition to that used when also used as an encapsulant). In embodiments where a liquid filling such as a room temperature vulcanize filling is used as the cured layer 38, the adhesive 16 is optional. FIG. 4 illustrates another view of the PV module assembly of FIG. 3. An integrated silicone oil tank can be located underneath the second layer 18 and can provide a thermosiphon effect. The use of a fluid layer with a low viscosity (e.g., less than or equal to 1,000 centipoise can allow heat transfer from the PV cells to the atmosphere through the thermosiphon principle (i.e., that hot oil is lighter than cold oil, so the hot oil rises to the top).

Examples of PV cells include single crystal silicon, polycrystalline silicon, amorphous silicon, silicon tandem cells, copper indium gallium selenide (CIGS), cadmium telluride (CdTe), and organic cells, as well as combinations comprising at least one of the foregoing. The various types of cells have different demands for moisture protection varying from protection against only liquid water to highly effective protection from water vapor making the moisture barrier optional.

A PV cell can be formed of layers of p-i-n semiconductive material. Optionally, each layer of which can, in turn, be formed of, a semiconductor alloy material (e.g., a thin film of such alloy material). In one embodiment, a p-i-n type PV device, such as a solar cell, can comprise individual p-i-n type cells. Below the lowermost cell can be a substrate (e.g., a transparent substrate) or a substrate comprising a metallic material such as stainless steel, aluminum, tantalum, molybdenum, chrome, or metallic particles embedded within an insulator (cermets). In some applications there is a thin oxide layer and/or a series of base contacts prior to the deposition of the amorphous semiconductor alloy material.

Each of the cells can be fabricated from a body of thin film semiconductor alloy material comprising silicon and hydrogen. Each of the bodies of semiconductor alloy material includes an n-type layer of semiconductor alloy material; a substantially intrinsic layer of semiconductor alloy material; and a p-type layer of semiconductor alloy material. The intrinsic layer can include traces of n-type or p-type dopant material without forfeiting its characteristic neutrality, hence it may be referred to as a “substantially intrinsic layer”.

Also, although p-i-n type photovoltaic cells are described, the methods and materials can also be used to produce single or multiple n-i-p type solar cells, p-n type cells or devices, Schottky barrier devices, as well as other semiconductor elements and/or devices such as diodes, memory arrays, photoresistors, photodetectors, transistors, etc. The term “p-i-n type”, as used herein, is defined to include any aggregation of n, i, and p layers operatively disposed to provide a photoresponsive region for generating charge carriers in response to absorption of photons of incident radiation.

The PV cell 14 converts the light energy into electrical energy. Several different types of PV cells 14 can be used. Suitable bulk technology PV cells 14 include amorphous silicon cells, multicrystalline silicon cells, and monocrystalline silicon cells. Suitable thin film technology PV cells 14 include cadmium telluride cells, copper indium selenide cells, gallium arsenide or indium selenide cells, and copper indium gallium selenide cells. In specific embodiments, the PV cell is a multicrystalline silicon PV cell or a monocrystalline silicon PV cell.

Generally, each type of PV cell has a “sweet spot”, or a range of wavelengths (light energy), which it converts most efficiently into electric energy. The PV cell should be selected so that its sweet spot matches, as much as possible, the transmitted light through the coating, first layer, and silicone oil combination. For example, the sweet spot of a multicrystalline silicon photocell or a monocrystalline silicon PV cell is about 700 nanometers to about 1100 nanometers.

The efficiency of a PV cell can be affected by the way the cell is produced. When PV cells are produced by cutting using a 30 micrometer diamond saw compared to laser guided water cutting, the PV cell may increase its efficiency by 1%. For example, PV cells can be produced using a DISCO DAD 321 cutter (available from Disco Corporation) operating at 30,000 rpm. See also U.S. Pat. No. 4,097,310, the disclosure of which is hereby fully incorporated by reference herein. Generally, it is desirable for the PV cell to have smooth edges and faces rather than rough edges and faces. The size (e.g., length and width) and shape of the PV cells can vary. Shapes can include various polygonal designs such as square, rectangular, and so forth. The length and width can, individually be up to about 200 millimeters (mm), specifically, 100 mm to 175 mm. Exemplary sizes include about 100 millimeter (mm) by about 100 mm, about 125 mm by about 125 mm, about 150 mm by about 150 mm, about 156 mm by about 156 mm, about 175 mm by about 175 mm, and about 200 mm to about 200 mm, about 100 mm by about 175 mm, and about 125 mm by about 150 mm.

Generally, a PV module comprises a first layer, a second layer, PV cells, a fluid layer and/or a cured layer between the first layer and the PV cells, a fluid layer and/or a cured layer between the PV cells and the second layer, an optional adhesive (e.g., a gel) between the second layer and the PV cells, and a backing material. The cured layer can optionally comprise a curable material such as poly(ethylene vinyl acetate) (EVA), silicone (e.g., silicone RTV, silicone TSE, etc.), thermoplastic materials (such as aliphatic polyurethanes and/or polyolefin ionomers), and combinations comprising at least one of the foregoing. The fluid layer can comprise silicone oil as previously described. The materials for the fluid layer and/or cured layer can be selected on the basis of clarity, adhesion, and mechanical protection provided to the PV cell.

The backing material can be selected according to the desired end use application of the PV module. For example, flexible PV modules can use a polymer film backing material while crystalline silicon cells can use a rigid backing material.

The first layer and the second layer can be connected to one another with the use of various attachment techniques. For example, the first layer and the second layer can be connected with an adhesive, such as glue or tape and/or even through the use of welding which can provide additional stiffness to the assembled PV module. PV cells can generally be dispersed between the first layer and the second layer. A fluid layer and/or a cured layer can be located between the first layer second surface and the PV cells and can function as an encapsulant providing an optical coupling between the first layer and the PV cells, while mechanically decoupling them. The fluid layer and/or cured layer can additionally aid in transporting heat out of the PV cells to the atmosphere, resulting in higher efficiency for the PV module over time. As described previously the second layer can be fully integrated with other features of the PV module assembly including, but not limited to the junction box, mounting points, and micro-inverter. A turbulent airflow to cool the PV module can be created by aerodynamic features integrated in the second layer. The aerodynamic features can include, but are not limited to, fins, ribs, baffles, and combinations comprising at least one of the foregoing. The first layer can optionally be textured to decrease light reflection away from the PV module, thereby increasing solar absorption of the PV module. Such a design with a textured first layer and/or aerodynamic features in the second layer can allow for a higher energy yield during a PV module's lifetime under different circumstances such as sunlight that enters at an angle, high ambient temperatures, and partial shading.

The first layer and second layer can form a stiff and light structure as compared to PV module assemblies where glass is present as one or both layers. For example, when the first layer and the second layer each, independently, comprise a plastic material and the second layer additionally comprises an integrated assembly including the junction box, cables, controllers, and mounting points, the production time and assembly time of the PV module assembly can be decreased. Generally, the second layer can function as a structural layer for the PV module assembly. When the second layer as disclosed herein comprises a plastic material, the second layer can optionally comprise a multiwall sheet comprising ribs and/or hollow sections to increase the stiffness of the second layer. The second layer can also comprise fillers such as glass or mineral fillers to increase the structural integrity and/or stiffness of the second layer. As mentioned, a fluid layer, e.g., silicone oil and/or a cured layer, e.g., silicone room temperature vulcanize filling, can be located between the first layer and the PV cells and optionally between the PV cells and the second layer to protect the PV cells from moisture and to provide an optical coupling between the first layer and the PV cells. The PV cells can be adhered to the second layer by any means. For example, an optional adhesive (e.g., silicone gel pads or PV cell supports) located on a side of the PV cells facing the second layer can be used to adhere the PV cells to the second layer. Alternatively or in addition to, integrated features such as a snap fit connection or distance holders in the first and/or second layer can be used to keep the PV cells in place without straining the cells. Integrated support studs molded on the second layer and/or on the first layer can also be used to keep the PV cells in place. In another alternative, room temperature vulcanize silicone can be used to adhere the PV cells to the second layer. In yet another embodiment, room temperature vulcanize silicone can be used as the cured layer without a fluid layer, serving a dual purpose of acting as an encapsulant around the PV cells and adhering the PV cells to the second layer.

As mentioned, the first layer can comprise a plastic material, such as polycarbonate, poly(methyl methacrylate), polyamide, and combinations comprising at least one of the foregoing. Using a plastic material for the first layer can allow for the incorporation of optical textures such as Fresnel lenses to increase the amount of light captured. Incorporating features such as triangles on a surface of the first layer adjacent to the fluid layer can capture light between the PV cells that would normally be lost. The use of a fluid layer and/or a cured layer with a low viscosity (e.g., less than or equal to 1,500 centipoise can allow heat transfer from the PV cells to the atmosphere through the thermosiphon principle (i.e., that hot oil is lighter than cold oil, so the hot oil rises to the top). As previously mentioned, aerodynamic features integrated in the second layer create turbulent airflow on a surface of the second layer facing the structure to which the PV module assembly is attached (e.g., roof). The turbulent air flow can allow the PV cells to operate at lower temperatures, thus increasing the efficiency of the PV module. In one embodiment, the fluid layer and/or cured layer can be selected so that the refractive index (RI) of these layers is close in value to the RI of the first layer, thus limiting the light lost between the fluid layer and/or cured layer and the first layer and further increasing the efficiency of the PV module. For example, the RI of polycarbonate is about 1.58 and the RI of silicone oil is about 1.4. In an embodiment, the refractive index of the material of the first layer can be within 15% of the refractive index of the material of the fluid layer. It can be desirable to tailor the RI of the fluid layer material and/or cured layer material such that it is closer to the value of the RI of the material of the first layer (e.g., closer to the RI value for polycarbonate).

The overall size of the module is a function of the process used to make the module, such as injection molding. The overall size of the module can be 1.0 meter (m) by 1.0 m, specifically, 0.7 m by 1.0 m. As previously described, the size of the individual PV cells in the module can be about 125 mm by about 125 mm, specifically about 156 mm by about 156 mm. The thickness of the first layer and the second layer can be, individually, about 1 mm to about 25 mm, specifically, about 2 mm to about 8 mm, more specifically, about 3 mm to about 6 mm, and even more specifically, about 3 mm. The thickness of the first layer and the second layer can be the same or different. The thickness of the cured layer and/or fluid layer can be about 0.5 mm to about 6 mm, specifically, about 1 mm to about 5 mm, more specifically, about 2 mm to about 4 mm, and even more specifically, about 2.5 mm to about 3.5 mm.

The use of a fluid layer and/or a cured layer as herein described in the PV module assembly offers several advantages. Firstly, there are no adhesion problems between the first layer, the fluid layer, and the PV cells. Second, water vapor will not condense on the soldering joints and will not affect light transmission. Third, the fluid layer and/or cured layer materials are inherently ultraviolet (UV) light stable and will not degrade over time compared to the use of an ethylene vinyl acetate (EVA) layer. Fourth, relating to the use of silicone oil as a fluid layer, the silicone oil can also be collected and reused after the useful life of the PV module.

A PV module can also comprise a first layer having a coating dispersed on the outermost surface of the first layer, e.g., a silicone hardcoat and/or a plasma coating. The plasma coating (e.g., EXATEC* E900 coating, commercially available from EXATEC LLC) ensures the PV module can function for a certain period of time, e.g., 20 years. In an embodiment, when the first layer and the second layer comprise polycarbonate, the first layer and second layer can either or both comprise planarizing layer(s) and/or organic-inorganic composition barrier coating layer(s) which can include a silicone hardcoat and/or a plasma treatment process. The barrier coating (which can be graded or non-graded) can comprise a zone substantially organic in composition and a zone substantially inorganic in composition. Some exemplary organic-inorganic composition barrier coatings are described in U.S. Pat. No. 7,449,246. Exemplary coating compositions for the organic-inorganic barrier layer are organic, ceramic and/or inorganic materials, as well as combinations comprising at least one of the foregoing. These materials can be reaction or recombination products of reacting plasma species and are deposited onto the substrate surface. Organic coating materials typically comprise carbon, hydrogen, oxygen, and optionally other elements, such as sulfur, nitrogen, silicon, etc., depending on the types of reactants. Exemplary reactants that result in organic compositions in the coating are straight or branched alkanes, alkenes, alkynes, alcohols, aldehydes, ethers, alkylene oxides, aromatics, silicones, etc., having up to 15 carbon atoms. Inorganic and ceramic coating materials typically comprise oxide; nitride; carbide; boride; or combinations comprising at least one of the foregoing of elements of Groups IIA, IIIA, IVA, VA, VIA, VIIA, IB, and IIB; metals of Groups IIIB, IVB, and VB; and rare-earth metals. For example, the barrier coating can have optical properties that are substantially uniform along an axis of light transmission, said axis oriented substantially perpendicular to the surface of the coating.

For example, silicon carbide can be deposited onto a substrate (e.g., the first layer or the second layer) by recombination of plasmas generated from silane (SiH₄) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum tartrate and ammonia. Other combinations of reactants may be chosen to obtain a desired coating composition. A graded composition of the coating is obtained by changing the compositions of the reactants fed into the reactor chamber during the deposition of reaction products to form the coating.

The barrier coating can have a transmission rate of oxygen through the barrier coating of less than or equal to 0.1 cubic centimeters per square meter-day (cm³/(m² day)), as measured at 25° C. with a gas containing 21 vol % oxygen. The water vapor transmission can be less than about 0.01 grams per square meter-day (g/(m² day)), as measured at 25° C. and with a gas having 100% relative humidity.

Barrier layer(s) can be applied to polymer films by various methods such as chemical vapor deposition (e.g., plasma-enhanced chemical-vapor deposition, radio-frequency plasma-enhanced chemical-vapor deposition, expanding thermal-plasma chemical-vapor deposition, electron-cyclotron-resonance plasma-enhanced chemical-vapor deposition, and inductively-coupled plasma-enhanced chemical-vapor deposition), sputtering (e.g., reactive sputtering), and so forth, as well as combinations comprising at least one of the foregoing. Some such methods are described in U.S. Pat. No. 7,015,640 and U.S. Patent Publication No. 2006/0001040.

The planarizing layer can comprise a resin such as an epoxy based resin (cycloaliphatic resin), an acrylic based resin, a silicone resin, as well as combinations comprising at least one of the foregoing. One example of a planarizing layer is a UV-cured acrylic-colloidal silica coating such as the LEXAN* HP-H UV-cured acrylic-colloidal silica coating commercially available from the Specialty Film and Sheet business unit of SABIC Innovative Plastics. The planarizing layer, and/or other coatings, can further include additive(s) such as flexibilizing agent(s), adhesion promoter(s), surfactant(s), catalyst(s), as well as combinations comprising at least one of the foregoing. In some embodiments, the planarizing layer thickness can be 1 nanometer (nm) to 100 micrometers (μm). Often the planarizing layer thickness can be 100 nm to 10 μm, specifically, 500 nm to 5 μm.

The planarizing layer can be substantially smooth and substantially defect free. The term “average surface roughness” Rₐ is defined as the integral of the absolute value of the roughness profile measured over an evaluation length. The term “peak surface roughness” Rₚ is the height of the highest peak in the roughness profile over the evaluation length. The term “substantially smooth” means the average surface roughness Rₐ is less than or equal to 4 nm, specifically, less than or equal to 2 nm, and more specifically, less than or equal to 0.75 nm. The peak surface roughness Rₚ can be less than or equal to 10 nm, specifically less than or equal to 7 nm, and more specifically, less than or equal to 5.5 nm. Substantially defect free means the number of point defects is less than or equal to 100 per square millimeter (mm²), specifically, less than or equal to 10/mm², and more specifically, 1/mm²

The application of these layers results in a very hard, UV stable, and moisture resistant outer surface of the first layer and/or the second layer, while retaining the impact properties of the polycarbonate.

Methods of making the PV module assemblies disclosed herein are also contemplated. For example, in one embodiment, a method of making a PV module assembly can comprise disposing a photovoltaic cell between a first layer where the first layer has a first layer first surface and a first layer second surface and between a second layer where the second layer has a second layer first surface and a second layer second surface. The first layer can be transparent and can comprise a plastic material. The second layer can also comprise a plastic material. A connecting layer (e.g., adhesive tape, which can also act as a structural adhesive), can be attached to the second layer and then to the first layer (or vice versa), where the connecting layer can form a gap between the first layer second surface and the second layer first surface. The connecting layer can be disposed between and in physical contact with the surfaces of the first layer and the second layer. For example, the connecting layer can be disposed between and in physical contact with the first layer second surface and the second layer first surface. Once the first layer and the second layer have been attached, a liquid filling can be inserted into the gap to form a fluid layer and/or a cured layer. The cured layer can be a fluid having a viscosity of less than or equal to 1,500 centipoise before curing, where the cured layer is cured after insertion into the gap or after insertion between the first layer and the second layer.

The first layer can also optionally comprise a filling opening and a degassing opening to facilitate insertion of the liquid filling into the gap, where the filling opening and the degassing opening can be sealed after insertion of the liquid filling into the gap. The filling opening and degassing opening can optionally be sealed with a plastic button. Electrical components of the photovoltaic cell can be embedded into the connecting layer before the liquid filling is inserted into the gap. A junction box, controllers, cables, and a micro-inverter can be incorporated into the second layer before attaching the connecting layer. The liquid filling can have a viscosity of less than or equal to 1,500 centipoise before curing.

The PV module as a whole can be designed to meet several Underwriters Laboratory (UL) and International Electrotechnical Commission (IEC) standards. Table 1 lists the various components of the PV module assembly and the tests that the each component can be designed to meet.

TABLE 1
PV Module Assembly Components and Standards

| | |
|---|---|
| PV Cells | UL 1703, IEC 61215, IEC 61646, IEC 61730, |
| | UL 790, UL-SU 8703, IEC 61701, IEC 62108 |
| Junction Box | UL 1703, UL 746C, IEC 61730-1 |
| Connector | UL-SU 6703 |
| GFCI | UL 1741 |
| Polymeric Materials | UL-SU 5703 |
| (e.g., second layer) | |
| Mounting System | UL-SU 1703-A |
| Tracking System | UL-SU 9703 |
| Cable for PV Cells | UL 4703, UL 854 (USE-2) |
| Combiner Box | UL 1741 |
| Inverter | UL 1741, IEC 61209 |

The PV cells, for example, can be designed to meet Paragraphs 7.3 and 7.4 of UL 1703 Edition 3_{—}2008. Paragraph 7.3 of UL 1703 states that a polymeric substrate or superstrate shall have a thermal index, both electrical and mechanical, as determined in accordance with the Standard for Polymeric Materials—Long Term Property Evaluations, UL 746B, not less than 90° C. (194° F.). In addition, the thermal index shall not be less than 20° C. (36° F.) above the measured operating temperature of the material. All other polymeric materials shall have a thermal index (electrical and mechanical) 20° C. above the measured operating temperature. The measured operating temperature is the temperature measured during the open-circuit mode for Temperature Test, Section 19, or the temperature during the short-circuit mode, whichever is greater. Paragraph 7.4 states that a polymeric material that serves as the outer enclosure for a module or panel that: a) is intended to be installed in a multi-module or multi-panel system; or b) has an exposed surface area greater than 10 square feet (ft²) (0.93 square meters (m²)) or a single dimension larger than 6 feet (ft) (1.83 meters (m)) shall have a flame spread index of 100 or less as determined under the Standard Method of Test for Surface Flammability of Materials Using a Radiant Heat Energy Source, ASTM E162-2001.

The PV module assembly can also be designed to meet the requirements set forth in Paragraph 30 of UL 1703, which describes the impact test. In order to pass the test, when a module is impacted as described below, there shall be no accessible live parts as defined in Section 15, Accessibility of Uninsulated Live Parts. Breakage of the superstrate material is acceptable provided there are no particles larger than 1 square in 6.5 square centimeters (cm²) released from their normal mounting position. The impact test is described as follows in Paragraph 30.3 of UL 1703, a module or panel is to be mounted in a manner representative of its intended use, and is to be subjected to a 5 foot pound (ft-lb) (6.78 Joule (J)) impact normal to the surface resulting from a 2 inch (51 millimeter (mm) diameter smooth steel sphere weighing 1.18 pounds (lb) (535 grams (g)) falling through a distance of 51 inches (1.295 m). The module or panel is to be struck at any point considered most vulnerable. If the construction of a module or panel does not permit it to be struck free from above by the free falling sphere, the sphere is to be suspended by a cord and allowed to fall as a pendulum through the vertical distance of 51 inches (1.295 m) with the direction of impact normal to the surface. For a polymeric wiring enclosure, the test is to be performed on the enclosure at 25° Celsius (C.) (77° Farenheit (F.)) and also after being cooled and maintained for 3 hours at a temperature of minus 35.0±2.0° C. (minus 31.0±3.6° F.).

IEC 61215 Edition 2_{—}2005 provides requirements for the design qualification and type approval of terrestrial photovoltaic modules appropriate for long term operation in general open air climates. Paragraph 10.11 of IEC 61215 provides a thermal cycling test for photovoltaic assemblies. The modules are subjected to a thermal cycling test where the temperature is cycled from −40° C.±2° C. to 85° C.±2° C. and each cycle is no longer than 6 hours and the total cycle time is 1,000 hours. The photovoltaic module assemblies disclosed herein can maintain greater than or equal to 95% of the maximum power output after being exposed to a thermal cycling of −40° C.±2° C. to 85° C.±2° C. for 1,000 hours. Paragraph 10.12 of IEC 61215 provides a humidity-freeze test to determine the ability of the module to withstand the effects of high temperature and humidity followed by sub-zero temperatures. The modules are subject to a cycle of 85% relative humidity ±5% for 20 minutes and a recovery time of 2 to 4 hours. Ten such cycles are performed before the module is evaluated to determine if the maximum output power has decreased greater than 5% compared to the value measured before the test. If so, the module is considered to have failed the test. Paragraph 10.13 of IEC 61215 provides a damp heat test carried out in a climatic chamber capable to carry out the test in accordance with IEC 60068-2-3 at conditions of 85° C.±2° C. with an 85% relative humidity ±5%. The purpose of this test is to determine the ability of the module to withstand long term exposure to penetration of humidity by applying the conditions described above for 1,000 hours. The severity of this test particularly challenges the lamination process and the edge sealing from humidity. Delamination and corrosion of cell parts can be observed as a result of humidity penetration.

IEC 61646 Edition 2_{—}2008 provides requirements for the design qualification and type approval of terrestrial thin film photovoltaic modules appropriate for long term operation in general open air climates as defined in IEC 60721-2-1. IEC 62108 describes the minimum requirements for the design qualification and type approval of concentrator photovoltaic modules and assemblies appropriate for long term operation in general open air climates as defined in IEC 60721-2-1. IEC 61701 determines the resistance of the module to corrosion from salt mist, looking at highly corrosive wet atmospheres, such as marine environments and temporary corrosive atmospheres that are also present in places where salt is used in winter periods to melt ice formations on streets and roads.

The PV module assemblies as described herein are further illustrated by the following non-limiting examples.

### EXAMPLES

### Example 1

PV module assemblies were made and tested for various physical properties to help determine acceptable combinations of materials for the PV module assemblies. The module assemblies were 20 cm by 30 cm with a second layer comprising a polycarbonate multiwall sheet (LEXAN* Thermoclear, commercially available from SABIC Innovative Plastics) having a thickness of 25 mm and a first layer comprising a UV protected polycarbonate sheet (LEXAN EXELL* D, commercially available from SABIC Innovative Plastics) having a thickness of 3 mm to 5 mm as indicated in Table 3. The overall thickness of the module varied depending on the thickness of the first layer. The thickness of the first layer varied between samples as illustrated in Table 2. In these samples, one PV cell was encapsulated between the polycarbonate first layer, cured layer (e.g., encapsulant), and polycarbonate second layer. Table 2 contains a description of the materials used, while Table 3 lists formulations for the individual assemblies that were tested. Polycarbonate 1 (PC1) was the UV protected polycarbonate sheet described above, which was a transparent polycarbonate sheet with UV protection on both sides of the sheet to offer weathering on both sides of the sheet.

Silicone room temperature vulcanize filling 1 (Silicone RTV1) was a low viscosity liquid silicone that cures to form a very soft gel like elastomer. Silicone RTV1 was a clear, solventless, two component material that can offer primerless adhesion to various substrates. Silicone RTV1 cures under ambient temperatures, where the cure time can be greater than 24 hours. Silicone rubber or thermoset elastomer 1 (Silicone TSE1) was a two component rubber or thermoset elastomer (TSE) silicone that cures in 1 hour at 80° C. Silicone TSE1 has a low viscosity that can enhance flow and fill in narrow spaces and around complex geometries. Silicone TSE1 can also offer primerless adhesion to various substrates and has a long working time at room temperature. Silicone rubber or thermoset elastomer 2 (Silicone TSE2) was a two component TSE silicone that cures at temperatures of 60° C. to 80° C. Primer 1 was an air drying primer supplied as a dilute solution of moisture reactive materials in volatile siloxane and can be used to improve both the quality and speed of adhesion development to room temperature vulcanizing silicone sealants to a variety of common non-porous substrates.

Comparative PV module assemblies were also tested. Comparative Samples 1 to 4 (C1 to C4) comprised a glass first layer having a thickness of 4 mm, EVA encapsulant having a thickness of 1 mm embedded with a PV cell, and a polytetrafluoroethylene-polyethylene terephthalate second layer. The PV module assemblies were 20 cm by 30 cm.

In Samples 1 to 6, the assemblies were created by applying a connecting layer (e.g., a spacer tape) on the circumference of the second layer to create a gap to be filled. The connecting layer also functioned as a structural adhesive. The tape was sticky on both sides, so that it sufficiently stuck to the first layer and the second layer. The connection wires of the PV cell were embedded in the tape, sealing the wires. Before attaching the first layer to the second layer, two holes were drilled in the first layer. One hole was for filling (e.g., inserting the encapsulant (i.e., liquid filling) into the area between the first layer, second layer, and PV cells) and one was for degassing. After the first layer was attached to the second layer, the open space between the first layer and the second layer (e.g., cavity) was filled with the encapsulant. Once filled, the filling and degassing holes were sealed (e.g., with plastic buttons etc.).

TABLE 2
Material Description

| Component | Material | Description | Available from |
|---|---|---|---|
| First Layer | PC1 | LEXAN* EXELL* D | SABIC |
| | | Sheet | Innovative |
| | | | Plastics |
| Encapsulant | Silicone RTV1 | 2 component RTV | Momentive |
| | | silicone; RTV 6166 | Performance |
| | | | Materials |
| Encapsulant | Silicone TSE1 | 2 component TSE | Dow |
| | | silicone; SE-1740 | Corning ® |
| Encapsulant | Silicone TSE2 | 2 component TSE | Zhermack |
| | | silicone; 35-15 | Glass |
| Connecting | Connecting | VHB 4915F | 3M ™ |
| Layer | Layer 1 | | |
| Connecting | Connecting | TDS 9508-9515 foam | 3M ™ |
| Layer | Layer 2 | tape | |
| Primer | Primer 1 (used | OS 1200 | Dow |
| | with Adhesive 2) | | Corning ® |

TABLE 3
Sample Formulations

| | First | First Layer | | Encapsulant | |
|---|---|---|---|---|---|
| Sample | Layer | thickness | Encap- | thickness | Connecting |
| No. | Material | (mm) | sulant | (mm) | Layer |
| 1 | PC1 | 3.0 | RTV1 | 0.5 | Connecting |
| | | | | | Layer 1 |
| 2 | PC1 | 4.0 | RTV1 | 0.5 | Connecting |
| | | | | | Layer 1 |
| 3 | PC1 | 5.0 | RTV1 | 0.5 | Connecting |
| | | | | | Layer 1 |
| 4 | PC1 | 3.0 | RTV1 | 1.5 | Connecting |
| | | | | | Layer 1 |
| 5 | PC1 | 4.0 | RTV1 | 1.5 | Connecting |
| | | | | | Layer 1 |
| 6 | PC1 | 5.0 | RTV1 | 1.5 | Connecting |
| | | | | | Layer 1 |
| C1 | Glass | 4.0 | EVA | N/A | N/A |
| C2 | Glass | 4.0 | EVA | N/A | N/A |
| C3 | Glass | 4.0 | EVA | N/A | N/A |
| C4 | Glass | 4.0 | EVA | N/A | N/A |
| 7 | PC1 | 4.0 | TSE1 | 1.5 | Connecting |
| | | | | | Layer 1 |
| 8 | PC1 | 4.0 | TSE1 | 1.5 | Connecting |
| | | | | | Layer 2 |
| 9 | PC1 | 4.0 | TSE2 | 1.5 | N/A |

The modules were subjected to a damp heat test according to IEC 61215 Paragraph 10.13 as previously described. Samples 1 to 6 passed the damp heat test, meaning that after 1,000 hours of being subjected to 85° C.±2° C. and 85%±5% relative humidity, no evidence of major visual defects were observed (e.g., delamination, bubbles, spots, etc.). Sample 7 had excellent filling quality, meaning that upon a visual inspection, there were no delamination spots or bubbles, but Adhesive 1 and TSE1 reacted with one another upon the elevated curing temperature, leading to bubble formation on the edges of the taped area and thus, leading to a fail in the damp heat test. In Sample 8, Adhesive 2, instead of Adhesive 1, was used to solve this problem. Sample 8 also passed the damp heat test and a thermal cycling test as set for in IEC Paragraph 10.11 (thermal cycling) and Paragraph 10.13 (damp heat), as previously described. Sample 9 additionally contained a primer as it was observed that TSE2 by itself did not sufficiently adhere to the polycarbonate to be able to pass the damp heat test. Use of Primer 1, however, led to whitening of the polycarbonate, which is not desirable for the first layer of a PV module assembly.

In Table 4, results are illustrated for measurements of the current of the PV module assemblies after conditioning for the damp heat test.

TABLE 4
Current and Crack Tests

| Sample # | I (A) | Crack in Cell |
|---|---|---|
| 1 | 4.34 | Yes |
| 2 | 4.36 | Yes |
| 3 | 4.20 | Yes |
| 4 | 4.38 | No |
| 5 | 4.40 | Yes |
| 6 | 4.49 | No |
| Average | 4.36 | |
| C1 | 4.58 | No |
| C2 | 4.63 | No |
| C3 | 4.71 | No |
| C4 | 4.72 | No |
| Average | 4.66 | |

As can be seen in Table 4, the electric current (I), measured in Amperes (A), for Samples 1 to 6 was comparable to the electric current measured for C1 to C4 after conditioning for the damp heat test, indicating that the assemblies disclosed herein can provide an alternative to glass modules. Cracks in the cell were observed for Samples 1, 2, 3, and 5 compared to no cracks for Samples 4 and 6 and no cracks for C1 to C4.

### Example 2

In this example, 8 photovoltaic module assemblies were built with one crystalline silicon PV cell, a first layer, and a second layer. The first layer in each of Samples 10 to 17 comprised a sheet made from a composition comprising polycarbonate (LEXAN* LS2 or LEXAN* DSS1259, commercially available from SABIC Innovative Plastics) and the second layer composition varied between a sheet comprising polycarbonate (LEXAN* 101, commercially available from SABIC Innovative Plastics) or a sheet comprising a blend of polyphenylene ether and polystyrene sheet (PPE, NORYL* V0150B, commercially available from SABIC Innovative Plastics). After assembly of the components of the PV module assembly, the samples were filled with silicone fluid (Momentive™ SF96-100) through an opening in the first layer. Another opening in the first layer was used for venting (i.e., degassing). Table 5 describes the material compositions, while Table 6 illustrates the components of the PV module assemblies. Assembly of the module was accomplished by gluing or laser welding as illustrated in Table 6.

Sample 10 was made from an injection molded first layer comprising PC1 with a plasma deposited EXATEC* E900 coating on the outermost surface of the first layer. Samples 11 to 17 were made from an extruded first layer comprising PC2 with a silicone hard coat on the outermost surface of the first layer. Samples 10, 11, 12, 16, and 17 had a polycarbonate second layer, while Samples 13, 14, and 15 had a polyphenylene ether/polystyrene second layer. Comparative Sample 5 (C5) had a glass first layer and a polyvinyl fluoride second layer. The first and second layers of Samples 10-12 were adhered to one another with a one part, neutral alkoxy-cure silicone sealant, the first and second layers of Samples 13-15 were adhered to one another with a two-part methacrylate adhesive, and the first and second layers of Samples 16 and 17 were adhered to one another by laser welding.

TABLE 5
Material Description

| Component | Description |
|---|---|
| PC1 | polycarbonate, LEXAN* LS2 |
| PC2 | polycarbonate, LEXAN* DSS1159 |
| PPE | polyphenyle ether/polystyrene, NORYL* V0150B |
| Coating 1 | EXATEC* E900 by plasma deposition |
| Coating 2 | Silicone hard coat |
| Adhesion 1 | one-part, neutral alkoxy-cure silicone sealant, |
| | Dow Corning ® PV804 |
| Adhesion 2 | two-part methacrylate adhesive PLEXUS ® MA3940 |
| PVF | polyvinyl fluoride, DuPont ® Tedlar ® |

TABLE 6
PV Module Assembly Compositions

| | First Layer | Second Layer | Method of |
|---|---|---|---|
| Sample # | Composition | Composition | Adhesion |
| 10 | PC1 + Coating 1 | PC1 | Adhesion 1 |
| 11 | PC2 + Coating 2 | PC1 | Adhesion 1 |
| 12 | PC2 + Coating 2 | PC1 | Adhesion 1 |
| 13 | PC2 + Coating 2 | PPE | Adhesion 2 |
| 14 | PC2 + Coating 2 | PPE | Adhesion 2 |
| 15 | PC2 + Coating 2 | PPE | Adhesion 2 |
| 16 | PC2 + Coating 2 | PC1 | Laser weld |
| 17 | PC2 + Coating 2 | PC1 | Laser weld |
| C5 | Glass | PVF | Lamination |

After the PV module assemblies were made, they were subject to various testing including efficiency, as measured in a flash tester. In this test, a module is tested for efficiency and then subjected to the conditions set forth in IEC 60068-2-3 at 85° C.±2° C. with an 85% relative humidity ±5% after which another efficiency is again measured. Here, since the fluid leaked from the filling and venting openings after being subjected to the damp heat test conditions, efficiency was not measured after the damp heat test. Efficiency as measured before the damp heat test is illustrated in Table 7. Thermal cycling was also measured according to Paragraph 10.11 Edition 2_{—}2005 of IEC 61215, and damp heat testing as measured according to Paragraph 10.13 Edition 2_{—}2005 of IEC 61215. The PV module assemblies were also visually inspected (i.e., by an unaided human eye) for cell and/or module breakage. Paragraph 10.11 of IEC 61215 provides a thermal cycling test for photovoltaic assemblies. The modules are subjected to a thermal cycling test where the temperature is cycled from −40° C.±2° C. to 85° C.±2° C. and each cycle is no longer than 6 hours and the total cycle time is 1,000 hours. Paragraph 10.13 of IEC 61215 provides a damp heat test carried out in a climatic chamber capable to carry out the test in accordance with IEC 60068-2-3 at conditions of 85° C.±2° C. with an 85% relative humidity ±5%. The purpose of this test is to determine the ability of the module to withstand long term exposure to penetration of humidity by applying the conditions described above for 1,000 hours. The severity of this test particularly challenges the lamination process and the edge sealing from humidity. Delamination and corrosion of cell parts can be observed as a result of humidity penetration.

As can be seen from Table 7, in Samples 10 to 17, the silicone fluid leaked from the filling and venting openings during the thermal cycling and damp heat conditions, so the efficiency after cycling was not measured. TC100 in Table 7 refers to thermal cycling for 100 cycles, while DH500 refers to damp heat conditions for 500 hours. As can be seen in Table 7, no cell or module breakage occurred (i.e., no delamination) after the tests and the efficiency of the modules was similar to that of C5.

TABLE 7
Results from PV Module Assembly Tests

| | | Damp Heat | Breakage |
|---|---|---|---|
| Sample # | Efficiency (%) | Testing | (Y/N) |
| 10 | 14.9 | TC100 | N (leakage) |
| 11 | 14.6 | DH500 | N (leakage) |
| 12 | 14.5 | DH500 | N (leakage) |
| 13 | 14.5 | DH500 | N (leakage) |
| 14 | 14.8 | TC100 | N (leakage) |
| 15 | 14.6 | DH500 | N (leakage) |
| 16 | 14.8 | TC100 | N (leakage) |
| 17 | 14.8 | DH500 | N (leakage) |
| C5 | 15.3 | N/A | N/A |

The PV module assembly disclosed herein can be designed to weigh approximately 10 kilograms per square meter (kg/m²) compared to 13 kg/m² for PV modules containing a glass first layer and/or aluminum frame. The layers of the PV module can be formed from a thermoplastic composition by a variety of means such as injection molding, extrusion, rotational molding, blow molding, and thermoforming. In an embodiment, forming is accomplished by injection molding. Injection molding allows for a mass produceable module without necessitating the laminating process used in modules containing a glass first layer. As a result, the assembly time for the PV module can decrease from greater than or equal to 20 minutes to about 1 minute to about 5 minutes, specifically, about 2 minutes to about 3 minutes. Installation of the PV module assembly can be easier and less time consuming since the PV module is lighter and as mentioned, incorporates integrated mounting points which allow for easy installation. Additionally, the use of micro-inverters can allow the system to be a plug and play without the need for a separate inverter installation step. The overall cost of the PV module assembly can be decreased by about 10% due to the faster assembly time and shorter installation time partly because of the integration of the junction box and inverter. Overall yield of the module due, for example, to partial shading, imperfect placement of the modules, or high ambient temperature, will be higher compared to other modules, further decreasing the cost of the PV module by 20%. For example, the overall yield of the module can be greater than or equal to 10% higher compared to other modules, specifically, greater than or equal to 20% higher, more specifically, greater than or equal to 25%, even more specifically, greater than or equal to 50%, and still more specifically, greater than or equal to 75% higher. A further advantage of the PV module assembly disclosed herein can be found in the recyclability aspects of the module. For example, after the usable life of 20 years, the module can be easily disassembled and PV cells recouped and refitted for assembly in a new module. The first layer and the second layer can be reground and reused in a new second layer or structural support part. Finally, the fluid layer comprising silicone fluid can be recouped and reused in a new module.

The PV module assemblies can be used in solar power generation applications in various manners such as building facades, on rooftops (such as a skylight or roofing tile), in highway/railroad sound barriers, greenhouses, dual purpose window glazing, and commercial buildings.

In an embodiment, a photovoltaic module assembly, comprises: a photovoltaic cell; a transparent first layer comprising a plastic material, wherein the first layer has a first layer first surface and a first layer second surface; a second layer, wherein the second layer has a second layer first surface and a second layer second surface, wherein the photovoltaic cell is between the first layer second surface and the second layer first surface; and a cured layer between the first layer second surface and the second layer first surface, wherein the cured layer is a fluid having a viscosity of less than or equal to 1,500 centipoise before curing.

In an embodiment, a photovoltaic module assembly, comprises: a photovoltaic cell; a transparent first layer comprising a plastic material, wherein the first layer has a first layer first surface and a first layer second surface; a second layer comprising a plastic material, wherein the second layer has a second layer first surface and a second layer second surface, wherein the photovoltaic cell is between the first layer second surface and the second layer first surface; a connecting layer disposed between the first layer second surface and the second layer first surface, wherein the connecting layer forms a gap between the first layer first surface and the second layer second surface, wherein the photovoltaic cell is in the connecting layer; and a cured layer in the gap, between the first layer and the photovoltaic cell.

In an embodiment, a method of making a photovoltaic module assembly, comprises: disposing a photovoltaic cell between a first layer having a first layer first surface and a first layer second surface and a second layer having a second layer first surface and a second layer second surface, wherein the first layer is transparent and comprises a plastic material and wherein the second layer comprises a plastic material; and inserting a liquid filling between the first layer and the second layer, wherein the liquid filling has a viscosity of less than or equal to 1,500 centipoise before curing; and curing the liquid filling.

In the various embodiments, (i) the photovoltaic module assembly further comprises a connecting layer disposed between and in physical contact with the first layer second surface and the second layer first surface, wherein the connecting layer forms a gap between the first layer first surface and the second layer second surface; and/or (ii) the cured layer comprises a room temperature vulcanize filling; and/or (iii) the room temperature vulcanize filling comprises a silicone room temperature vulcanize and/or a silicone thermoset elastomer; and/or (iv) the connecting layer comprises an acrylic foam tape; and/or (v) the cured layer is a fluid having a viscosity of less than or equal to 1,5000 centipoise before curing; and/or (vi) the assembly further comprises a coating disposed on the first layer first surface and/or on the second layer second surface, wherein the coating comprises a silicone hard coat, a plasma coating, and combinations comprising at least one of the foregoing; and/or (vii) the first layer and/or the second layer comprises polycarbonate; and/or (viii) the second layer comprises a blend of polyphenylene ether and polystyrene; and/or (ix) the refractive index of the first layer is within 15% of the refractive index of the fluid layer; and/or (x) the assembly further comprises a junction box, controllers, cables, and a micro-inverter in the second layer; and/or (xi) the second layer comprises a multiwall sheet; and/or (xii) the method further comprises attaching the first layer to the second layer with a connecting layer forming a gap therebetween, wherein the connecting layer is disposed between and in physical contact with the first layer second surface and the second layer first surface; and/or (xiii) the liquid filling of the fluid layer comprises a room temperature vulcanize filling and/or (xiv) the liquid filling comprises a silicone room temperature vulcanize; and/or (xv) the first layer comprises a filling opening; and/or (xvi) the first layer comprises an outgassing opening; and/or (xvii) further comprising closing the filling opening and/or the outgassing opening after the liquid filling is inserted; and/or (xviii) further comprising embedding electrical components of the photovoltaic cell into the connecting layer before the liquid filling is inserted.

In one embodiment, a photovoltaic module assembly comprises: a photovoltaic cell; a transparent first layer comprising a first layer plastic material; a second layer comprising a second layer plastic material, wherein the photovoltaic cell is between the first layer and the second layer; and a fluid layer between the first layer and the photovoltaic cell, wherein the fluid layer has a viscosity of 0 to 1,000 centipoise.

In one embodiment, a method of making a photovoltaic module assembly comprises: disposing a photovoltaic cell between a first layer and a second layer, wherein the first layer is transparent and comprises a first layer plastic material and wherein the second layer comprises a second layer plastic material; and disposing a fluid layer between the first layer and the photovoltaic cell, wherein the fluid layer has a viscosity of 0 to 1,000 centipoise.

In the various embodiments: (i) the fluid layer comprises silicon oil; (ii) the photovoltaic module assembly further comprises a coating disposed on the first layer and/or on the second layer, wherein the coating comprises a silicon hard coat, a plasma coating, and combinations comprising at least one of the foregoing; and/or (iii) the first layer and/or the second layer comprise polycarbonate; and/or (iv) the second layer comprises a blend of polyphenylene ether and polystyrene; and/or (v) the refractive index of the first layer is within 15% of the refractive index of the fluid layer; and/or (vi) the assembly comprises a flame spread index of less than or equal to 100 as determined under ASTM E162-2001; and/or (vii) the assembly maintains greater than or equal to 95% of the maximum power output after being exposed to a thermal cycling of −40° C.±2° C. to 85° C.±2° C. for no greater than 6 hours, wherein the total cycle time is 1,000 hours according to IEC 61215 Ed. 2-2005; and/or (viii) the assembly has a total weight of 5 to 10 kilograms per square meter; and/or (ix) the photovoltaic module assembly further comprises a junction box, controllers, cables, and a micro-inverter in the second layer; and/or (x) the photovoltaic cells are adhered to the second layer by a support selected from the group consisting of silicon gel pads, integrated support studs molded on the second layer, and combinations comprising at least one of the foregoing; and/or (xi) the photovoltaic module assembly further comprises a second fluid layer between the second layer and the photovoltaic cell; and/or (xii) the method further comprises incorporating a junction box, controllers, cables, and a micro-inverter in the second layer.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Furthermore, the terms “first,” “second,” and the like, herein do not denote any order, quantity, or importance, but rather are used to determine one element from another. The terms “a” and “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more films). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A photovoltaic module assembly, comprising:
a photovoltaic cell;
a transparent first layer comprising a plastic material, wherein the first layer has a first layer first surface and a first layer second surface;
a second layer, wherein the second layer has a second layer first surface and a second layer second surface, wherein the photovoltaic cell is between the first layer second surface and the second layer first surface; and
a cured layer between the first layer second surface and the second layer first surface, wherein the cured layer is a fluid having a viscosity of less than or equal to 1,500 centipoise before curing.

2. The photovoltaic module assembly of claim 1, further comprising a connecting layer disposed between and in physical contact with the first layer second surface and the second layer first surface, wherein the connecting layer forms a gap between the first layer first surface and the second layer second surface.

3. A photovoltaic module assembly, comprising:
a photovoltaic cell;
a transparent first layer comprising a plastic material, wherein the first layer has a first layer first surface and a first layer second surface;
a second layer comprising a plastic material, wherein the second layer has a second layer first surface and a second layer second surface, wherein the photovoltaic cell is between the first layer second surface and the second layer first surface;
a connecting layer disposed between the first layer second surface and the second layer first surface, wherein the connecting layer forms a gap between the first layer first surface and the second layer second surface, wherein the photovoltaic cell is in the connecting layer; and
a cured layer in the gap, between the first layer and the photovoltaic cell.

4. The photovoltaic module assembly of any of claims 3, wherein the cured layer comprises a room temperature vulcanize filling.

5. The photovoltaic module assembly of claim 4, wherein the room temperature vulcanize filling comprises a silicone room temperature vulcanize and/or a silicone thermoset elastomer.

6. The photovoltaic module assembly of claim 3, wherein the cured layer is a fluid having a viscosity of less than or equal to 1,500 centipoise before curing.

7. The photovoltaic module assembly of claim 3, further comprising a coating disposed on the first layer first surface and/or on the second layer second surface, wherein the coating comprises a silicone hard coat, a plasma coating, and combinations comprising at least one of the foregoing.

8. The photovoltaic module assembly of claim 3, wherein the first layer and/or the second layer comprises polycarbonate.

9. The photovoltaic module assembly of claim 3, wherein the second layer comprises a multiwall sheet.

10. A method of making a photovoltaic module assembly, comprising:
disposing a photovoltaic cell between a first layer having a first layer first surface and a first layer second surface and a second layer having a second layer first surface and a second layer second surface, wherein the first layer is transparent and comprises a plastic material and wherein the second layer comprises a plastic material; and
inserting a liquid filling between the first layer and the second layer, wherein the liquid filling has a viscosity of less than or equal to 1,500 centipoise before curing; and
curing the liquid filling.

11. The method of claim 10, further comprising attaching the first layer to the second layer with a connecting layer forming a gap therebetween, wherein the connecting layer is disposed between and in physical contact with the first layer second surface and the second layer first surface.

12. The method of claim 10, wherein the liquid filling comprises a room temperature vulcanize filling.

13. The method of claim 12, wherein the liquid filling comprises a silicone room temperature vulcanize.

14. The method of claim 10, wherein the first layer comprises a filling opening.

15. The method of claim 14, wherein the first layer comprises an outgassing opening.

16. The method of claim 15, further comprising closing the filling opening and/or the outgassing opening after the liquid filling is inserted.

17. The method of claim 10, further comprising embedding electrical components of the photovoltaic cell into the connecting layer before the liquid filling is inserted.

18. A photovoltaic module assembly, comprising:
a photovoltaic cell;
a transparent first layer comprising a first layer plastic material;
a second layer comprising a second layer plastic material, wherein the photovoltaic cell is between the first layer and the second layer; and
a fluid layer between the first layer and the photovoltaic cell, wherein the fluid layer has a viscosity of 0 to 1,000 centipoise.

19. The photovoltaic module assembly of claim 18, wherein the fluid layer comprises silicon oil.

20. The photovoltaic module assembly of claim 18, further comprising a coating disposed on the first layer and/or on the second layer, wherein the coating comprises a silicon hard coat, a plasma coating, and combinations comprising at least one of the foregoing.

21. The photovoltaic module assembly of claim 18, wherein the first layer and/or the second layer comprise polycarbonate.

22. The photovoltaic module assembly of claim 21, wherein the second layer comprises a blend of polyphenylene ether and polystyrene.

23. The photovoltaic module assembly of claim 18, wherein the refractive index of the first layer is within 15% of the refractive index of the fluid layer.

24. The photovoltaic module assembly of claim 18, wherein the assembly has a total weight of 5 to 10 kilograms per square meter.

25. The photovoltaic module assembly of claim 18, further comprising a junction box, controllers, cables, and a micro-inverter in the second layer.

26. The photovoltaic module assembly of claim 18, wherein the photovoltaic cells are adhered to the second layer by a support selected from the group consisting of silicon gel pads, integrated support studs molded on the second layer, and combinations comprising at least one of the foregoing.

27. The photovoltaic module assembly of claim 18, further comprising a second fluid layer between the second layer and the photovoltaic cell.

28. A method of making a photovoltaic module assembly, comprising:
disposing a photovoltaic cell between a first layer and a second layer, wherein the first layer is transparent and comprises a plastic material and wherein the second layer comprises a plastic material; and
disposing a fluid layer between the first layer and the photovoltaic cell, wherein the fluid layer has a viscosity of 0 to 1,000 centipoise.

29. The method of claim 28, wherein the fluid layer comprises silicon oil.

30. The method of claim 28, further comprising incorporating a junction box, controllers, cables, and a micro-inverter in the second layer.
